(19) United States
(12) Patent Application Publication
(10) Pub. No.: US 2025/0174481 A1
(43) Pub. Date: May 29, 2025

(54) SUBSTRATE TRANSPORT APPARATUS AND SUBSTRATE PROCESSING APPARATUS INCLUDING THE SAME

(71) Applicant: SCREEN Holdings Co., Ltd., Kyoto (JP)

(72) Inventors: Takuya SATO, Kyoto (JP); Hiroyuki KAWAHARA, Kyoto (JP); Yuichi TAKAYAMA, Kyoto (JP)

(21) Appl. No.: 18/957,648

(22) Filed: Nov. 22, 2024

(30) Foreign Application Priority Data
Nov. 29, 2023 (JP) 2023-202086

(51) Int. Cl. H01L 21/68; H01L 21/687

(52) U.S. Cl. CPC H01L 21/68; H01L 21/68707

(57) ABSTRACT

In a case where both of a first sensor and a second sensor respectively sense that a substrate is placed on a first guide and a second guide, a pusher is allowed to change from an open state to a closed state. On the other hand, in a case where at least one of the first sensor and the second sensor does not sense the substrate, the pusher is prohibited from changing from the open state to the closed state.

This application claims priority to Japanese Patent Application No. 2023-202086 filed Nov. 29, 2023, the subject matter of which is incorporated herein by reference in entirety.

### BACKGROUND OF THE INVENTION

The present invention relates to a substrate transport apparatus that transfers various substrates such as a semiconductor substrate, a substrate for flat panel display (FPD), such as liquid crystal display and organic electroluminescence (EL) display, a glass substrate for a photomask, and an optical disk substrate, and a substrate processing apparatus including the substrate transport apparatus.

### DESCRIPTION OF THE RELATED ART

Conventionally, as a substrate transport apparatus realizing substrate transport required for substrate processing, there is a substrate transport apparatus having a hand main body having a plurality of tactile sensors. When the substrate is placed on the plurality of tactile sensors, the tactile sensors detect the force in the Z-axis direction. In this way, it is possible to recognize that the substrate is normally placed on the hand main body. It is also possible to detect the angular deviation of the hand main body in the Z-axis direction by the tactile sensors.

### LIST OF DOCUMENTS

JP 2022-91240 A

However, a conventional substrate transport apparatus including a tactile sensor is not configured to fully utilize the tactile sensor. For example, according to the configuration of JP 2022-91240 A, abnormality in substrate transport is merely detected by using a tactile sensor.

At present, there is a demand for a substrate transport apparatus capable of transporting various types of substrates. Such a substrate transport apparatus needs to realize transport of a substrate on the basis of a plurality of transport modes. It is considered that the tactile sensor can detect the state of the substrate placed on the hand main body, but a specific configuration for realizing this has not been studied.

### SUMMARY OF THE INVENTION

The present invention has been made in view of such circumstances, and an object thereof is to provide a substrate transport apparatus capable of efficiently transporting various types of substrates and a substrate processing apparatus including the substrate transport apparatus.

That is, the present invention is a substrate transport apparatus having a hand capable of transporting a substrate in a horizontal posture, in which
the hand includes
   a base member,
   a first guide provided on an upper surface of the base member, supporting a peripheral edge lower portion of a substrate, and coming in contact with an outer peripheral surface of the substrate,
   a first sensor configured to sense that the substrate is placed on the first guide,
   a second guide provided on the upper surface of the base member, supporting the peripheral edge lower portion of the substrate, and coming in contact with the outer peripheral surface of the substrate,
   a second sensor configured to sense that the substrate is placed on the second guide, and
   a pusher provided on the upper surface to face the first guide and the second guide and being movable forward and backward toward the first guide and the second guide,
the substrate transport apparatus includes a pusher driving unit configured to advance and retract the pusher, and
a control unit configured to control the pusher driving unit,
the control unit is configured to cause the pusher to be switchable between
   an open state in which the pusher is separated from the outer peripheral surface of the substrate placed on the first guide and the second guide, and
   a closed state in which the pusher comes into contact with the outer peripheral surface of the substrate to press the substrate against the first guide and the second guide and to catch and hold the substrate, and
when the substrate is received by the hand with the pusher in the open state, the control unit is configured
   to allow the pusher to change from the open state to the closed state in a case where both of the first sensor and the second sensor respectively sense that the substrate is placed on the first guide and the second guide, and
   to prohibit the pusher from changing from the open state to the closed state in a case where at least one of the first sensor and the second sensor does not sense the substrate.

### [Operation and Effect]

According to the above configuration, the first sensor sensing that the substrate is placed on the first guide, the second sensor sensing that the substrate is placed on the second guide, and the pusher provided to face the first guide and the second guide and being movable forward and backward toward the first guide and the second guide are provided. In a case where both of the first sensor and the second sensor respectively sense that the substrate is placed on the first guide and the second guide, the pusher is allowed to change from the open state to the closed state, and in a case where at least one of the first sensor and the second sensor does not sense the substrate, the pusher is prohibited from changing from the open state to the closed state. With such a configuration, the state of the substrate can be grasped using the first sensor and the second sensor. That is, in a case where both of the first sensor and the second sensor respectively sense that the substrate is placed on the first guide and the second guide, it can be determined that the shape of the substrate is close to a flat shape. On the other hand, in a case where at least one of the first sensor and the second sensor does not sense the substrate, it can be determined that the shape of the substrate is far from a flat shape. As described above, when the state of the substrate is known, the opening and closing of the pusher can be appropriately controlled according to the state of the substrate. Therefore, according to the present invention, it is possible to provide a substrate transport apparatus capable of efficiently transporting various types of substrates.

In the substrate transport apparatus, it is preferable that in a case where both of the first sensor and the second sensor respectively sense that the substrate is placed on the first guide and the second guide, the control unit is configured
to determine a time difference between a time point at which the first sensor senses that the substrate is placed on the first guide and a time point at which the second sensor senses that the substrate is placed on the second guide by comparing both the time points,
to allow the pusher to change from the open state to the closed state in a case where the time difference is within a predetermined reference time difference, and
to prohibit the pusher from changing from the open state to the closed state in a case where the time difference exceeds the predetermined reference time difference.

### [Operation and Effect]

According to the above configuration, even in a case where both of the first sensor and the second sensor respectively sense that the substrate is placed on the first guide and the second guide, the state of the substrate can be accurately sensed. That is, according to the above configuration, the time point at which the first sensor senses that the substrate is placed on the first guide and the time point at which the second sensor senses that the substrate is placed on the second guide are compared to determine the time difference therebetween. When the determined time difference is within the reference time difference, it can be determined that the shape of the substrate is close to a flat shape. When the determined time difference exceeds the reference time difference, it can be determined that the shape of the substrate is far from a flat shape. As described above, when the state of the substrate is known, the opening and closing of the pusher can be appropriately controlled according to the state of the substrate. Therefore, according to the present invention, it is possible to provide a substrate transport apparatus capable of efficiently transporting various types of substrates.

It is preferable that the substrate transport apparatus further includes a transport mechanism configured to move the hand,
in which the transport mechanism is configured to cause the hand to be switchable between a mode of moving the hand at a first moving speed and a mode of moving the hand at a second moving speed slower than the first moving speed, and
in a case where both of the first sensor and the second sensor respectively sense that the substrate is placed on the first guide and the second guide, the control unit is configured
   to determine a time difference between a time point at which the first sensor senses that the substrate is placed on the first guide and a time point at which the second sensor senses that the substrate is placed on the second guide by comparing both the time points,
   to allow the pusher to change from the open state to the closed state to catch and hold the substrate in a case where the time difference is within a predetermined reference time difference, and
   to further control the transport mechanism to move the hand catching and holding the substrate at the first moving speed, but
in a case where at least one of the first sensor and the second sensor does not sense the substrate and a case where the time point exceeds the predetermined reference time difference, the control unit is configured
   to prohibit the pusher from changing from the open state to the closed state to bring the substrate in a state of not being caught and held, and
   to further control the transport mechanism to move the hand at the second moving speed in a state where the substrate is not caught and held by the pusher.

### [Operation and Effect]

According to the above configuration, it is possible to switch a mode between a mode of moving the hand at a first moving speed and a mode of moving the hand at a second moving speed slower than the first moving speed. When the determined time difference is within the reference time difference, the pusher is changed from the open state to the closed state to move the hand at the first moving speed while the substrate is caught and held. When the determined time difference exceeds the reference time difference, the hand is moved at the second moving speed while the pusher is prohibited from changing from the open state to the closed state. Also in a case where the pusher is prohibited from changing from the open state to the closed state, the hand is moved at the second moving speed. With such a configuration, a substrate transport apparatus with a high throughput can be realized.

In the substrate transport apparatus, it is preferable that the control unit is configured to return the substrate to an original slot instead of moving the hand at the second moving speed in a state where the substrate is not caught and held by the pusher, in a case where at least one of the first sensor and the second sensor does not sense the substrate and a case where the time difference exceeds the predetermined reference time difference.

### [Operation and Effect]

According to the above configuration, when the pusher is prohibited from the open state to the closed state, transport of the substrate is stopped, and the substrate is returned to the original slot. With such a configuration, it is possible to provide a substrate transport apparatus in which a substrate far from a flat shape is not transported and dropping of a substrate is suppressed.

In the substrate transport apparatus, it is preferable that the first guide includes a support portion supporting the peripheral edge lower portion of the substrate and a wall portion coming into contact with the outer peripheral surface of the substrate, and
the second guide includes a support supporting the peripheral edge lower portion of the substrate and a wall portion coming into contact with the outer peripheral surface of the substrate.

### [Operation and Effect]

According to the above configuration, the first guide includes a support portion supporting the peripheral edge lower portion of the substrate and a wall portion coming into contact with the outer peripheral surface of the substrate, and the second guide includes a support supporting the peripheral edge lower portion of the substrate and a wall portion coming into contact with the outer peripheral surface of the substrate. With such a configuration, it is possible to provide a substrate transport apparatus capable of reliably transporting a substrate without dropping the substrate as much as possible.

In the substrate transport apparatus, it is preferable that the base member includes
a first blade,
a second blade, and
a connecting portion connecting the first blade and the second blade,
the pusher is disposed on the connecting portion,
the first guide is disposed on the first blade, and
the second guide is disposed on the second blade.

### [Operation and Effect]

According to the above configuration, the base member includes a first blade, a second blade, and a connecting portion connecting the first blade and the second blade. The pusher is disposed on the connecting portion, the first guide is disposed on the first blade, and the second guide is disposed on the second blade. With such a configuration, it is possible to provide a substrate transport apparatus capable of reliably catching and holding a substrate.

In the substrate transport apparatus, it is preferable that the first sensor is a tactile sensor and is provided between the base member and the first guide, and
the second sensor is a tactile sensor and is provided between the base member and the second guide.

### [Operation and Effect]

According to the above configuration, the first sensor and the second sensor are tactile sensors. With such a configuration, it is possible to reliably detect whether or not the substrate is placed on the first guide and the second guide. According to the above configuration, the first sensor is provided between the base member and the first guide. With such a configuration, the first sensor can reliably detect the placement of the substrate in the first guide. According to the above configuration, the second sensor is provided between the base member and the second guide. With such a configuration, the same effect as that of the first sensor is obtained.

In the substrate transport apparatus, it is preferable that in the first guide, the support portion and the wall portion are separated from each other,
the first sensor is provided between the base member and the support portion of the first guide,
in the second guide, the support portion and the wall portion are separated from each other, and
the second sensor is provided between the base member and the support portion of the second guide.

### [Operation and Effect]

According to the above configuration, in the first guide, the support portion and the wall portion are separated from each other, and the first sensor is provided between the base member and the support portion of the first guide. With such a configuration, it is possible to provide a substrate transport apparatus capable of detecting that a substrate has risen on a wall portion to determine the state of the substrate. According to the above configuration, in the second guide, the support portion and the wall portion are separated from each other, and the second sensor is provided between the base member and the support portion of the second guide. With such a configuration, the second sensor also has the same effect as the first guide described above.

In the substrate transport apparatus, it is preferable that the control unit is configured
to determine that the substrate is placed on the first guide when the first sensor detects a predetermined load, and
to determine that the substrate is placed on the second guide when the second sensor detects a predetermined load.

### [Operation and Effect]

According to the above configuration, it is preferable to determine that the substrate is placed on the first guide when the first sensor detects a predetermined load, and to determine that the substrate is placed on the second guide when the second sensor detects a predetermined load. With such a configuration, it is possible to provide a substrate transport apparatus that does not cause malfunction even when the first sensor and the second sensor detect noise.

In the substrate transport apparatus, it is preferable that the first sensor is embedded in a first recess formed in the base member, and
the second sensor is embedded in a second recess formed in the base member.

### [Operation and Effect]

According to the above configuration, the first sensor is embedded in a first recess formed in the base member, and the second sensor is embedded in a second recess formed in the base member. With such a configuration, it is possible to provide a substrate transport apparatus in which the thickness of a hand in a height direction is suppressed and the hand does not collide with a substrate during transport.

In a substrate processing apparatus including the substrate transport apparatus, it is preferable that the substrate processing apparatus includes a single-substrate-type processing unit configured to process substrates transported by the hand one by one.

### [Operation and Effect]

According to the above configuration, a single-substrate-type processing unit processing substrates transported by the hand one by one is provided. According to the above configuration, it is possible to provide a substrate processing apparatus capable of performing substrate processing while reliably transporting various types of substrates.

According to the present invention, it is possible to provide a substrate transport apparatus capable of efficiently transporting various types of substrates and a substrate processing apparatus including the substrate transport apparatus.

### BRIEF OF DESCRIPTION OF THE DRAWINGS

FIG. 1 is a plan view illustrating an overall configuration of a substrate processing apparatus of an embodiment;

FIG. 2 is a side view illustrating a carrier of an embodiment;

FIG. 3 is a left side view illustrating configurations of a taking hand and a returning hand of an embodiment;

FIG. 4 is a plan view illustrating the configurations of the taking hand and the returning hand of an embodiment;

FIG. 5 is an exploded perspective view illustrating the configuration of the taking hand of an embodiment;

FIG. 6 is an exploded perspective view illustrating the configuration of the taking hand of an embodiment;

FIG. 7 is a plan view illustrating an operation of the taking hand of an embodiment;

FIG. 8 is a cross-sectional view illustrating an operation of the taking hand of an embodiment;

FIG. 9 is a plan view illustrating an operation of the taking hand of an embodiment;

FIG. 10 is a plan view illustrating an operation of the taking hand of an embodiment;

FIG. 11 is a functional block diagram illustrating an operation of the taking hand of an embodiment;

FIG. 12 is a functional block diagram illustrating an operation of the taking hand of an embodiment;

FIG. 13 is a functional block diagram illustrating an operation of the taking hand of an embodiment;

FIG. 14 is a perspective view illustrating an operation of the taking hand of an embodiment;

FIG. 15 is a functional block diagram illustrating an operation of the taking hand of an embodiment;

FIG. 16 is a functional block diagram illustrating an operation of the taking hand of an embodiment;

FIG. 17 is a flowchart illustrating a flow of a substrate of an embodiment;

FIG. 18 is a schematic view illustrating a first modification of the present invention;

FIG. 19 is a schematic view illustrating the first modification of the present invention; and

FIG. 20 is a schematic view illustrating the first modification of the present invention.

### DESCRIPTION OF THE PREFERRED EMBODIMENTS

Hereinafter, embodiments of the present invention will be described with reference to the drawings. The following embodiment is a substrate processing apparatus on which a substrate transport apparatus of the present invention is mounted. The substrate transport apparatus of the present invention corresponds to an indexer block in the substrate processing apparatus of an embodiment. The indexer block has an indexer robot including a hand that transports a substrate.

### EMBODIMENT

### 1. Overall Configuration

As illustrated in FIG. 1, a substrate processing apparatus 1 of this example includes a load port 10, an indexer block 3, and a processing block 5. The substrate processing apparatus 1 of this example relates to single-substrate-type processing, and is configured to acquire substrates W in a horizontal posture one by one from a carrier C, perform the substrate processing, and return the substrates W one by one to the carrier.

In the present specification, for convenience, a direction in which the indexer block 3 and the processing block 5 in the substrate processing apparatus 1 are arranged is referred to as a “front-rear direction X”. The front-rear direction X extends horizontally. Of the front-rear direction X, a direction from the processing block 5 toward the indexer block 3 in the substrate processing apparatus 1 is referred to as “front”. A direction opposite to the front is referred to as “rear”. A direction extending horizontally orthogonal to the front-rear direction X is referred to as a “width direction Y”. One direction of the “width direction Y” is referred to as a “right side” for convenience, and the other direction is referred to as a “left side” for convenience. A direction (height direction) orthogonal to the front-rear direction X and the width direction Y is referred to as a “vertical direction Z” for convenience. In each drawing, front, rear, In each drawing, front, top, and bottom are appropriately shown for reference.

The load port 10 corresponds to a carrier placement shelf of the present invention. The load port 10 is a carrier placement shelf on which the carrier C is placed. A plurality of load ports 10 are arranged in the width direction Y, and each one of the carriers C can be placed. The load port 10 can place the carrier C in which substrates in a horizontal posture are stacked in the vertical direction and stored.

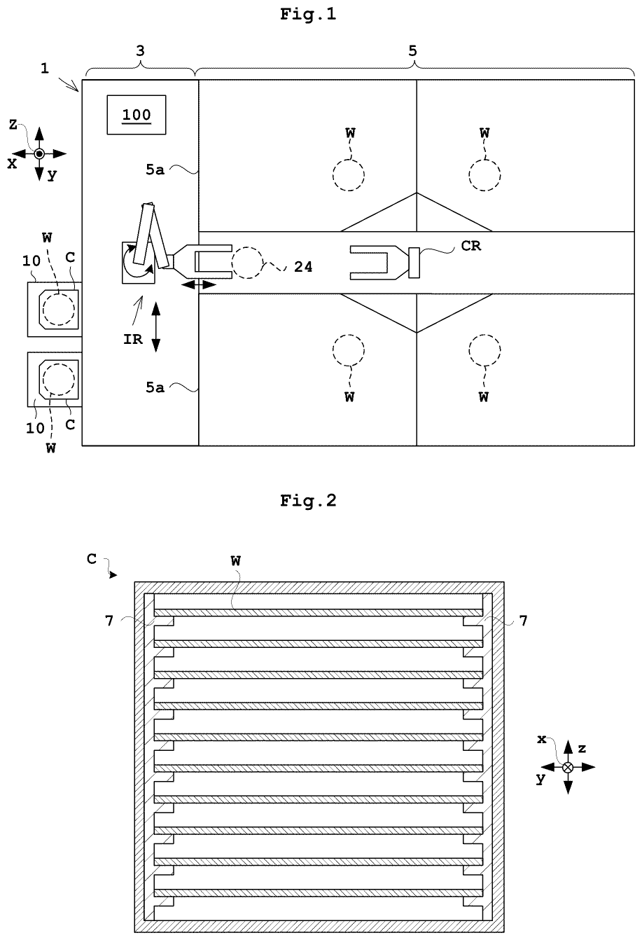

That is, the carrier C store a plurality of substrates W in the vertical direction Z at predetermined intervals in a horizontal posture. The carrier C is provided with an opening for taking out and storing a substrate on one side surface. A plurality of (for example, 25) substrates W are stacked and stored in one carrier C at regular intervals in a horizontal posture. FIG. 2 is a cross-sectional view illustrating the configuration of the carrier C. In the carrier C, a comb-shaped member 7 having a plurality of protrusions for placing the substrate W is provided at both ends of a carrier housing. The protrusion of the comb-shaped member 7 is configured to place the end portion of the substrate W. The protrusion extends in the front-rear direction X. The protrusions are arranged at intervals of 1 cm. A recess between the protrusions forms a slot in which the substrate W is accommodated. Examples of the carrier C include a sealed front opening unify pod (FOUP). In the present invention, an open type container may be employed as the carrier C.

The indexer block 3 corresponds to the substrate transport apparatus of the present invention. The indexer block 3 has a rectangular shape extending in the width direction Y. The indexer block 3 is provided with an indexer robot IR having a taking hand 11a and a returning hand 11b capable of transporting a substrate in a horizontal posture. The indexer robot IR is horizontally movable in the width direction Y. The indexer robot IR has a hand capable of holding and transporting the substrate W. The hand is supported by an articulated arm configured to be capable of turning, lifting, and advancing and retracting. The indexer robot IR can access the carrier C on the load port 10 and a path 24 provided in front of the processing block 5. The indexer robot IR can perform two operations including an operation of acquiring the substrates W in a horizontal posture one by one from the carrier C and placing the substrates W in the path 24, and an operation of acquiring the substrates W in the horizontal posture placed in the path 24 one by one and returning the substrates W to the carrier C. The non-processed substrate W held by the carrier C is transported to the path 24 by the indexer robot IR. The processed substrate W is placed on the path 24 and returned to the carrier C by the indexer robot IR.

The processing block 5 is configured to perform predetermined processing on the substrate W. In the processing block 5, a plurality of single-substrate-type processing chambers 5a are arranged. The single-substrate-type processing chamber 5a corresponds to the single-substrate-type processing unit of the present invention. The single-substrate-type processing chamber 5a is configured to process the substrates W transported by the taking hand 11a of the indexer robot IR described later one by one.

The arrangement of the single-substrate-type processing chambers 5a in the processing block 5 will be described. That is, in the processing block 5 of the present invention, three single-substrate-type processing chambers 5a are arranged in a middle layer region, an upper layer region, and a lower layer region, respectively, to form a laminate. Two laminates are arranged back and forth on the right side of the processing block 5. Similarly, two laminates are arranged back and forth on the left side of the processing block 5. Therefore, twelve single-substrate-type processing chambers 5a are mounted on the processing block 5.

A substrate transfer region extending in the front-rear direction X is provided in a central portion of the processing block 5. A center robot CR reciprocate in the substrate transfer region, and can acquire the substrates W in a horizontal posture from the path 24 one by one and transfer the substrates W to any one of the single-substrate-type processing chambers 5a. The center robot CR can acquire the substrates W in a horizontal posture held by the single-substrate-type processing chambers 5a one by one and return the substrates W to the path 24. As described above, the center robot CR can access each of the single-substrate-type processing chambers 5a and the path 24.

Examples of the substrate processing performed by the single-substrate-type processing chamber 5a include substrate cleaning processing. The substrate processing apparatus 1 of this example may be configured to perform various kinds of substrate processing using a chemical liquid in addition to the substrate cleaning processing.

### 2. Configuration of Indexer Robot

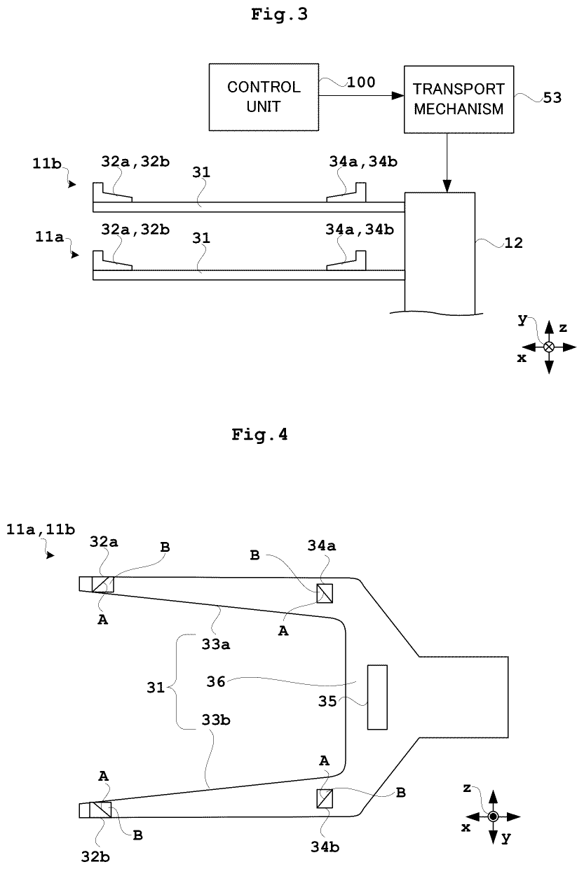

FIG. 3 schematically illustrates a distal end portion related to substrate holding in the indexer robot TR. The indexer robot IR includes the taking hand 11a and the returning hand 11b. The returning hand 11b and the taking hand 11a are held by an arm 12 in a stacked state in the vertical direction Z. The arm 12 can individually advance and retreat the returning hand 11b and the taking hand 11a in the front-rear direction X. In the configuration of FIG. 3, the returning hand 11b and the taking hand 11a are arranged in this order from the top to the bottom, but the arrangement order of the members can be appropriately changed.

A transport mechanism 53 performs transport of the substrate W by operating the arm 12 under the control of the control unit 100. When the transport mechanism 53 operates the arm 12, the taking hand 11a and the returning hand 11b also move accordingly. The transport mechanism 53 can move the taking hand 11a in the front-rear direction or the right-left direction. The transport mechanism 53 can also rotate the taking hand 11a about the vertical axis. As described above, the transport mechanism 53 is configured to move the taking hand 11a. The transport mechanism 53 also moves and rotates the returning hand 11b similarly to the taking hand 11a.

The taking hand 11a corresponds to the hand of the present invention. The taking hand 11a enters between the substrates W vertically adjacent to each other so as to hold the non-processed substrates W from the carrier C one by one and transport the substrates W to the path 24.

The taking hand 11a has a base member 31, a guide member 32a, and a guide member 32b. The guide member 32a and the guide member 32b correspond to the first guide and the second guide of the present invention. The base member 31 has a flat shape so as to be able to enter between the substrates. The guide member 32a and the guide member 32b are at the distal end portion of the taking hand 11a and are configured to bring the end portion of the substrate W into contact therewith. That is, the guide member 32a and the guide member 32b are tabs provided at the distal end of the base member 31 and are members in contact with the substrate W. The guide member 32a and the guide member 32b are provided on the upper surface of the base member 31. Thus, the guide member 32a and the guide member 32b are configured to support the peripheral edge lower portion of the upper substrate W. Therefore, the guide member 32a and the guide member 32b are configured to come into contact with the outer peripheral surface of the substrate.

The guide member 32a and the guide member 32b each have a support portion supporting the peripheral edge lower portion of the substrate W and a wall portion coming into contact with the outer peripheral surface. That is, the guide member 32a and the guide member 32b each have a thick portion and a thin portion. Therefore, the guide member 32a and the guide member 32b are partially different in thickness in the height direction. The end portion (bevel portion) of the substrate W can come into contact with the wall portion facing the proximal end portion of the taking hand 11a in the thick portion of each of the guide member 32a and the guide member 32b. The peripheral edge portion of the lower surface of the substrate can come into contact with the upward-facing support portion in the thin portion of each of the guide member 32a and the guide member 32b. The guide member 32a and the guide member 32b are provided on the upper surface of the base member 31, and the outer peripheral surface of the substrate is configured to come into contact therewith. The guide member is also provided at the proximal end portion of the base member 31, and this configuration will be described later.

Since the guide member 32a and the guide member 32b provided at the distal end portion of the base member 31 are tapered, this point will be described. The upper surface of the thin portion of each of the guide member 32a and the guide member 32b is inclined as illustrated in FIG. 3. That is, the thin portion is configured such that the thickness in the height direction decreases as it goes away from the thick portion. As described above, the guide member 32a and the guide member 32b each include a tapered portion (thin portion) that brings a lower portion of the substrate W into contact therewith, and a wall portion (side surface of the thick portion) that brings the outer peripheral surface of the substrate into contact therewith. The tapered portion of each of the guide member 32a and the guide member 32b corresponds to the support portion of the present invention.

Similarly, a guide member 34a and a guide member 34b provided at the proximal end portion of the base member 31 are tapered as illustrated in FIG. 3. That is, the thin portion is configured such that the thickness in the height direction decreases as it goes away from the thick portion. As described above, the guide member 34a and the guide member 34b each include a tapered portion (thin portion) that brings the lower portion of the substrate W into contact therewith, and a wall portion (side surface of the thick portion) that brings the outer peripheral surface of the substrate into contact therewith.

The returning hand 11b has the same configuration as the taking hand 11a described above. That is, the returning hand 11b has the base member 31, the guide member 32a, and the guide member 32b. In the returning hand 11b, the configuration in which the guide member 32a and the guide member 32b are provided at the distal end portion of the base member 31 and the configuration in which the guide member 32a and the guide member 32b each have a thick portion and a thin portion are the same as the configuration of the taking hand 11a. The returning hand 11b of this example is provided to transport the clean substrate W having been subjected to cleaning processing. By selectively using the hand in the forward path and the backward path in the reciprocating operation of the substrate W, it is not necessary to hold the substrate W after the cleaning processing by the hand holding the substrate W before the cleaning processing. Therefore, the cleanliness of the substrate W having been subjected to cleaning processing is maintained by providing the returning hand 11b.

The returning hand 11b does not necessarily need a first sensor 22a and a second sensor 22b to be described later.

FIG. 4 is a plan view illustrating the taking hand 11a and the returning hand 11b. The taking hand 11a and the returning hand 11b each include a connecting portion 36, and a first blade 33a and a second blade 33b branched from the connecting portion 36. The connecting portion 36 is configured to connect the first blade 33a and the second blade 33b. The first blade 33a is a member extending in the front-rear direction X to hold one end portion of the substrate W, and the second blade 33b is a member extending in the front-rear direction X to hold the other end portion of the substrate W.

The guide member 32a is disposed on the first blade 33a. The guide member 32a corresponds to the first guide of the present invention. The guide member 32b is disposed on the second blade 33b. The guide member 32b corresponds to the second guide of the present invention. The guide member 34a is disposed on the first blade 33a. The guide member 34b is disposed on the second blade 33b.

The wall portions A of the guide member 32a, the guide member 32b, the guide member 34a, and the guide member 34b are arranged so as to belong to an imaginary circle slightly larger than the substrate W. As a result, the substrate W can be accommodated in a receiving region of the substrate W constituted by the thin portions of the guide member 32a, the guide member 32b, the guide member 34a, and the guide member 34b.

The pusher 35 is a member provided on the upper surface of the base member 31. The pusher 35 is provided at the distal end portion of the connecting portion 36 so as to face the guide member 32a and the guide member 32b. The pusher 35 is on a line segment passing through an intermediate position between the guide member 32a and the guide member 32b and an intermediate position between the guide member 34a and the guide member 34b. The pusher 35 can push the substrate W held by the guide member 32a, the guide member 32b, the guide member 34a, and the guide member 34b in the front direction, that is, toward the guide member 32a and the guide member 32b. Therefore, the pusher 35 can advance and retreat toward the guide member 32a and the guide member 32b. The pusher 35 can move backward to be in the open state, and can move forward to be in the closed state. In order for the first blade 33a and the second blade 33b to grip the substrate W, first, the substrate W is held by the guide member 32a, the guide member 32b, the guide member 34a, and the guide member 34b with the pusher 35 in the open state. The substrate W is sandwiched between the guide member 32a and the guide member 32b, and the pusher 35 with the pusher 35 in the closed state. In this manner, the substrate W is caught and held.

### 3. Sensor

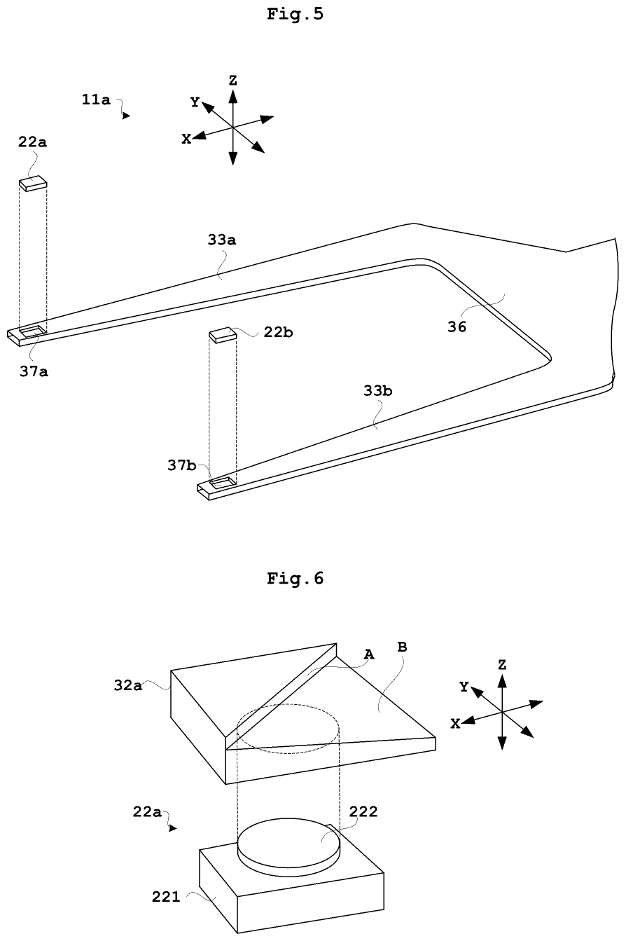

FIG. 5 is an exploded perspective view illustrating the configuration of the taking hand 11a. In FIG. 5, the guide member 32a, the guide member 32b, the guide member 34a, and the guide member 34b are not illustrated in order to facilitate understanding of the assembling structure of the sensor. A first recess 37a for embedding the first sensor 22a is provided at the distal end of the first blade 33a. Similarly, a second recess 37b for embedding the second sensor 22b is provided at the distal end of the second blade 33b.

As the first sensor 22a and the second sensor 22b, for example, a tactile sensor is used. Hereinafter, the first sensor 22a will be described as an example. FIG. 6 is an exploded perspective view illustrating a positional relationship between the first sensor 22a and the guide member 32a. The guide member 32a and the first sensor 22a are arranged in the Z direction. The first sensor 22a includes a main body 221 and an elastomer 222 including an elastic member. The main body 221 includes an electronic circuit, measures the weight and torque applied to the elastomer 222 in a three-dimensional direction, and outputs an electric signal. When the first sensor 22a is attached to the first blade 33a, the main body 221 is embedded in the first recess 37a, so that the elastomer 222 protrudes from the upper surface of the first blade 33a. The guide member 32a is fixed to the elastomer 222. Therefore, the first sensor 22a is a tactile sensor and is provided between the base member 31 and the guide member 32a. When the substrate W is placed on the guide member 32a, the elastomer 222 is deformed. Based on this, the first sensor 22a senses whether or not the substrate W has come into contact with the guide member 32a. That is, the first sensor 22a is configured to detect that the substrate W is placed on the guide member 32a.

More specifically, the first sensor 22a can detect a load applied to the guide member 32a. Therefore, the first sensor 22a outputs a signal indicating 0 mg in a case where the substrate W is not placed on the guide member 32a, and outputs a signal indicating the weight of the substrate in a case where the substrate W is placed on the guide member 32a. Particularly, since the substrate W is supported by the guide member 32a, the guide member 32b, the guide member 34a, and the guide member 34b, the weight of the substrate W is dispersed to each guide member. Therefore, the first sensor 22a outputs only a signal indicating a weight smaller than the total weight of the substrate W at the maximum.

The second sensor 22b has the same configuration as that of the first sensor 22a. That is, the second sensor 22b is configured to detect that the substrate W is placed on the guide member 32a.

The second sensor 22b can detect a load input to the guide member 32b. This point is the same as the configuration of the first sensor 22a.

When a predetermined load is detected, the first sensor 22a and the second sensor 22b determine that the substrate is placed on the first guide 32a and the second guide 32b.

### 4. Configuration of Pusher

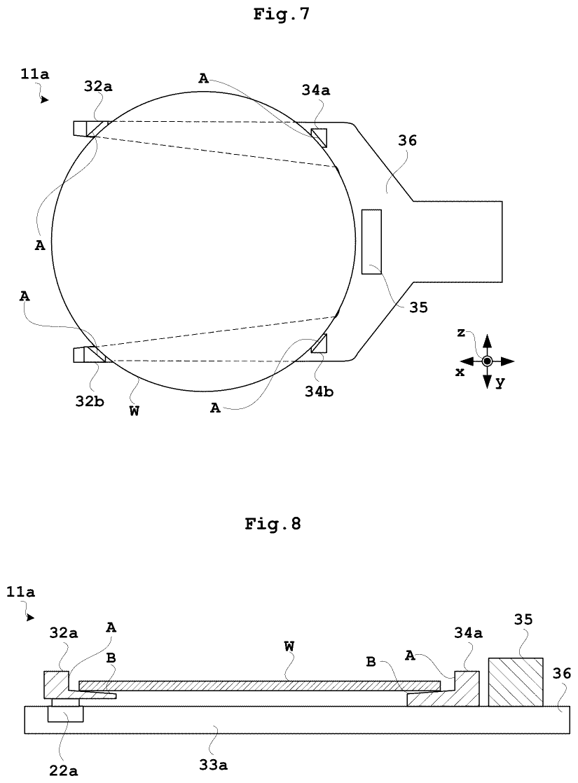

Hereinafter, the state change of the pusher 35 will be specifically described. FIG. 7 illustrates a state of the taking hand 11a when the pusher 35 is in the open state. The substrate W at this time is accommodated in a substrate receiving portion constituted by the wall portions A of the guide member 32a, the guide member 32b, the guide member 34a, and the guide member 34b. Since the substrate receiving portion is a region having a diameter larger than that of the substrate W, a gap is interposed between each wall portion A and the substrate W. The substrate W at this time is in a state of being placed on the guide member 32a and the guide member 32b.

FIG. 8 is a cross-sectional view of the taking hand 11a when the pusher 35 is in the open state. The guide member 32a and the guide member 34a are in contact with the outer peripheral surface of the substrate at the tapered portion B. Although not illustrated in FIG. 8, the guide member 32b is also in contact with the outer peripheral surface of the substrate W at the tapered portion B. The outer peripheral surface of the substrate W is located away from the wall portion A of each guide member.

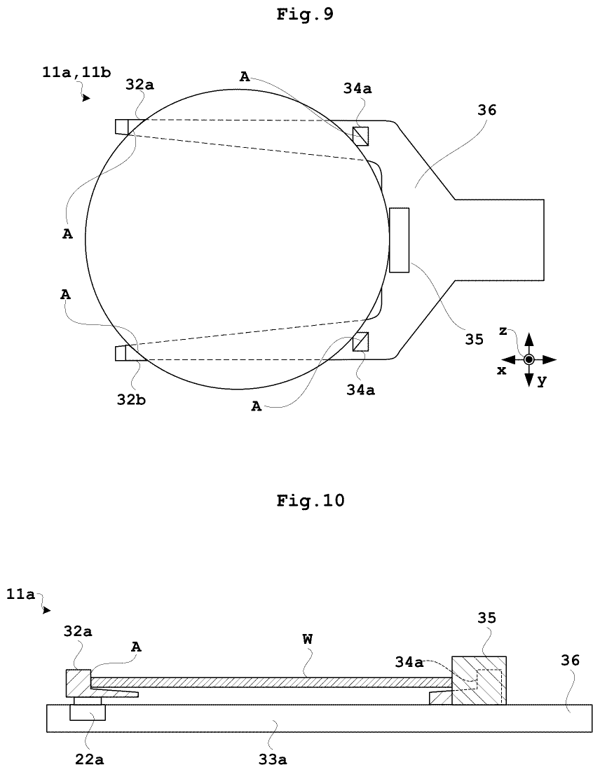

FIG. 9 illustrates a state of the taking hand 11a when the pusher 35 is in the closed state. The substrate W at this time is pressed by the pusher 35 and gripped (caught and held) by the taking hand 11a. As can be seen with reference to FIG. 9, the substrate W is pressed by the pusher 35 and comes into contact with the wall portion A of the guide member 32a. Although not illustrated in FIG. 9, the wall portion A of the guide member 32b also comes into contact with the substrate W. The substrate W comes into contact with the wall portion A on the outer peripheral surface. As described above, the substrate W when the pusher 35 is in the closed state is caught and held by three points of the pusher 35, the guide member 32a, and the guide member 32b. When the pusher 35 presses the substrate W, the substrate W is separated from the guide member 34a and the guide member 34b. In this manner, the pusher 35 can be switched between the open state and the closed state.

FIG. 10 is a cross-sectional view of the taking hand 11a when the pusher 35 is in the closed state. According to this drawing, the substrate W is pressed against the guide member 32a by the pusher 35, whereby the substrate is gripped by the guide member 32a and the pusher 35. At this time, the substrate W is separated from the wall portions A of the guide member 34a and the guide member 34b. When the substrate W is pressed by the pusher 35 in this manner, the substrate W is fixed to the taking hand 11a, so that the substrate W can be reliably transported.

### 5. Control of Pusher

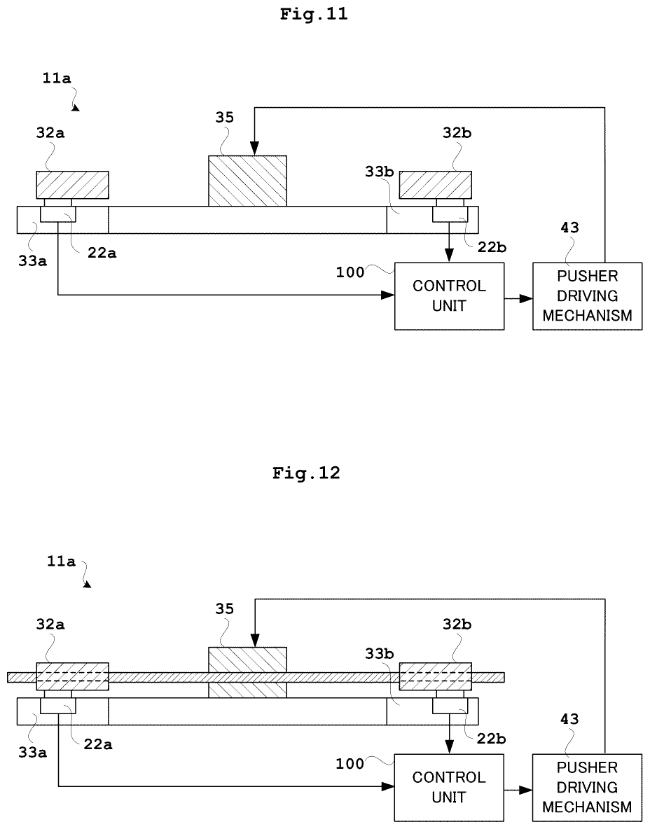

FIG. 11 is a view of the taking hand 11a as viewed from the X direction. Hereinafter, control of the pusher 35 will be described with reference to FIG. 11. A pusher driving mechanism 43 can advance and retract the pusher 35 along the first blade 33a and the second blade 33b. That is, the pusher driving mechanism 43 is configured to displace the pusher 35. The pusher driving mechanism 43 includes, for example, a servomotor or an air cylinder.

The control unit 100 is configured to control the pusher driving mechanism 43. That is, the control unit 100 can switch the pusher 35 between the open state and the closed state. When the pusher 35 is in the open state, the substrate W is in a state of being placed on the guide member 32a, the guide member 32b, the guide member 34a, and the guide member 34b. When the pusher 35 is in the closed state, the pusher 35 can also press the substrate W to catch and hold the substrate W by the taking hand.

The open state of the pusher 35 refers to a state where the pusher 35 is separated from the outer peripheral surface of the substrate placed on the guide member 32a and the guide member 32b. The closed state of the pusher 35 refers to a state where the pusher 35 comes into contact with the outer peripheral surface of the substrate W and presses the substrate W against the guide member 32a and the guide member 32b to catch and hold the substrate W.

When the substrate W is not placed, the first sensor 22a and the second sensor 22b do not sense the substrate W. As described above, when neither the first sensor 22a nor the second sensor 22b senses the substrate W, the control unit 100 receives the outputs of the first sensor 22a and the second sensor 22b to set the state of the pusher 35 to the open state.

FIG. 12 illustrates a state when the substrate W is received by the taking hand 11a. When the substrate W is placed on the guide member 32a, the load of the substrate W is transmitted through the guide member 32a and reaches the first sensor 22a. The first sensor 22a measures the load derived from the substrate applied to the guide member 32a. A signal indicating each weighing result is input to the control unit 100.

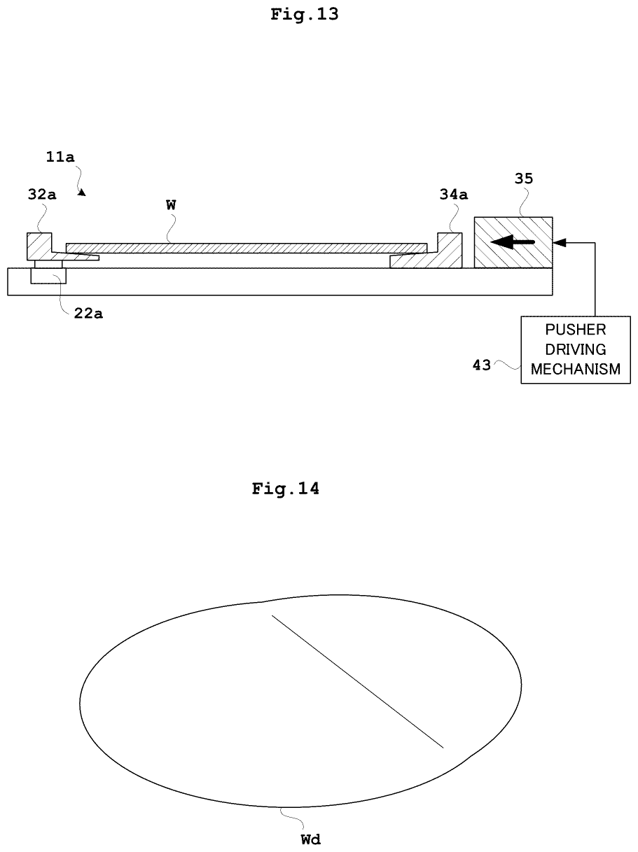

In a case where the substrate W is received by the taking hand 11a with the pusher 35 in the open state and both of the first sensor 22a and the second sensor 22b respectively sense that the substrate W is placed on the first guide 32a and the second guide 32b, the control unit 100 allows the pusher 35 to change from the open state to the closed state. Based on this, as illustrated in FIG. 13, the pusher driving mechanism 43 causes the pusher 35 to be in the closed state and presses the substrate W by the pusher 35.

On the other hand, a substrate Wd illustrated in FIG. 14 is not flat, and a peripheral edge, which should come into contact with the guide member 32a, protrudes upward. If the pusher 35 is set to be in the closed state when such a substrate Wd is transported by the taking hand 11a, the substrate Wd may be damaged or the substrate Wd may fall off from the taking hand 11a. The control unit 100 operates on the assumption that the taking hand 11a may acquire the substrate Wd.

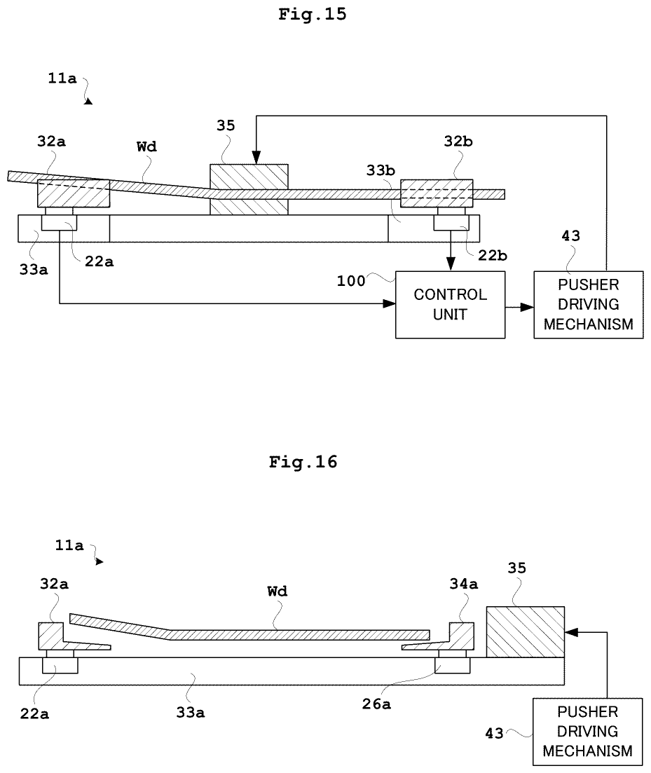

FIG. 15 illustrates a state when the substrate Wd illustrated in FIG. 14 is received by the taking hand 11a. Since the substrate Wd is not flat, the substrate Wd is not in contact with the guide member 32a even after being received by the taking hand 11a. Therefore, the first sensor 22a at this time does not output the signal of sensing the substrate Wd to the control unit 100. On the other hand, since the substrate Wd comes into contact with the guide member 32b, the second sensor 22b outputs a signal of sensing the substrate Wd and a signal indicating a load applied to the guide member 32b to the control unit 100.

As described above, in a case where the second sensor 22b senses that the substrate W is placed on the guide member 32b and the first sensor 22a does not sense that the substrate W is placed on the guide member 32a, the control unit 100 prohibits the pusher 35 from changing from the open state to the closed state.

In the example of FIG. 15, the second sensor 22b senses the substrate W, but the configuration of the present embodiment is also assumed to be a case where the first sensor 22a senses the substrate W instead of the second sensor 22b. That is, in a case where the first sensor 22a senses that the substrate W is placed on the guide member 32a and the second sensor 22b does not sense that the substrate W is placed on the guide member 32b, the control unit 100 prohibits the pusher 35 from changing from the open state to the closed state.

In the example of FIG. 15, the second sensor 22b senses the substrate W, but the configuration of the present embodiment is also assumed to be a case where neither the first sensor 22a nor the second sensor 22b senses the substrate W. The position of the substrate W to be stored in the carrier C is detected in advance by a mapping operation before the taking hand 11a is inserted into the carrier C. Therefore, it is already sensed that the substrate W is located in a predetermined slot without using the taking hand 11a. The taking hand 11a is moved to below the substrate Win order to scoop up the substrate W detected by the mapping operation. However, depending on the warpage of the substrate W, the substrate W may lift up to both the guide member 32a and the guide member 32b, and may be supported by the guide member 34a and the guide member 34b. In such as case, the substrate W is not sensed by the first sensor 22a and the second sensor 22b although the substrate W is present. Also in such a case, the control unit 100 prohibits the pusher 35 from changing from the open state to the closed state.

In short, in the configuration of the present embodiment, in a case where the shape of the substrate W is close to a flat shape, the displacement of the pusher 35 to the closed state is allowed, and in a case where the shape of the substrate W is far from a flat shape, the displacement of the pusher 35 to the closed state is prohibited. In other words, in a case where at least one of the first sensor 22a and the second sensor 22b does not sense the substrate W, the displacement of the pusher 35 to the closed state is prohibited.

In the example of FIG. 15, also in a case where the first sensor 22a does not sense the substrate W but the second sensor 22b senses the substrate W, the displacement of the pusher 35 to the closed state may be prohibited, and thus, this point will be described.

In the example of FIG. 15, since the shape of the substrate W is far from a flat shape, the first sensor 22a does not detect the substrate W. However, in a case where the shape of the substrate W is closer to a flat shape, not only the second sensor 22b but also the first sensor 22a may sense the substrate W. In the present embodiment, the substrate W having such a small distortion can be distinguished from the flat substrate W. Also in a case where the distortion of the substrate W placed on the taking hand 11a is small, the displacement of the pusher 35 to the closed state is prohibited.

That is, in a case where both the first sensor 22a and the second sensor 22b respectively sense that the substrate W is placed on the guide member 32a and the guide member 32b, the control unit 100 performs the following operation. First, the control unit 100 compares a time point at which the first sensor 22a senses that the substrate W is placed on the guide member 32a and a time point at which the second sensor 22b senses that the substrate W is placed on the guide member 32b to determine a time difference therebetween. In a case where the time difference is within a predetermined reference time difference, the control unit 100 allows the pusher 35 to change from the open state to the closed state. On the other hand, in a case where the time difference exceeds the predetermined reference time difference, the control unit 100 prohibits the pusher 35 from changing from the open state to the closed state.

Such an operation of the control unit 100 utilizes the fact that, when there is a distortion in the substrate W, a time difference occurs between sensing of the first sensor 22a and sensing of the second sensor 22b. When the substrate W is flat, the first sensor 22a and the second sensor 22b should sense the substrate W at the same time. However, when there is a distortion in the substrate W, a time difference is generated between detection timings of the first sensor 22a and the second sensor 22b according to the distortion of the substrate W. The control unit 100 of the present embodiment operates utilizing this time difference without missing a small distortion of the substrate W.

### 6. Movement Control of Taking Hand

The substrate processing apparatus 1 of the present embodiment can change the moving speed of the moving speed of the taking hand 11a according to the state of the substrate W, and thus this point will be described. That is, the transport mechanism 53 of the present embodiment can switch a mode between a high-speed mode in which the taking hand 11a is moved at a first moving speed and a low-speed mode in which the taking hand 11a is moved at a second moving speed slower than the first moving speed.

The configuration related to the high-speed mode will be described. The control unit 100 determines the time difference in detection as described above in a case where the first sensor 22a senses that the substrate W is placed on the guide member 32a and the second sensor 22b senses that the substrate W is placed on the guide member 32b. In a case where the time difference is within the reference time difference, the pusher 35 is changed from the open state to the closed state, and the substrate W is caught and held by the taking hand 11a. At this time, the transport of the substrate W is executed at the high-speed mode, and the substrate W is transported at the first moving speed. Since the substrate W is firmly supported on the taking hand 11a by the pusher 35, the substrate W does not slide off the taking hand 11a even when the substrate W is transported at a high speed.

The configuration related to the low-speed mode will be described. In a case where the first sensor 22a senses that the substrate is placed on the guide member 32a and the second sensor 22b does not sense that the substrate is placed on the guide member 32b, the control unit 100 prohibits the pusher 35 from changing from the open state to the closed state so as to bring the substrate W in a state of not being caught and held. At this time, the transport of the substrate W is executed at the low-speed mode, and the substrate W is transported at the second moving speed.

Similarly, in a case where the second sensor 22b senses that the substrate is placed on the guide member 32b and the first sensor 22a does not sense that the substrate is placed on the guide member 32a, the control unit 100 controls the substrate W to be transported at the second moving speed with the pusher 35 in the open state. The control unit 100 controls the substrate W to be transported at the second moving speed with the pusher 35 in the open state when the time difference exceeds the reference time difference even in a case where the first sensor 22a senses that the substrate W is placed on the guide member 32a and the second sensor 22b senses that the substrate W is placed on the guide member 32b.

Instead of transporting the substrate W in the low-speed mode, a configuration in which the transport of the substrate is stopped can also be employed. In this case, the taking hand 11a once scoops up and holds the substrate W from the slot formed by the comb-shaped member 7 of the carrier C, but the control unit 100 determines that the substrate W cannot be transported, and causes the substrate W to be lowered and returned to the original slot. The taking hand 11a proceeds to acquire another substrate W stored in the carrier C. That is, even when a substrate that cannot be transported is mixed with the substrate W of the carrier C, the transport operation of the substrate W is continued without being stopped.

### 7. Other Configurations

As illustrated in FIG. 1, the indexer block 3 includes the control unit 100 related to control of the indexer robot IR. The control unit 100 is configured as, for example, a central processing unit (CPU). The specific configuration of the control unit 100 is not limited, and for example, the control related to the taking hand 11a and the control related to the returning hand 11b may be configured by a single processor or may be configured by individual processors.

Examples of the control related to the control unit 100 include control related to forward and backward movement of the taking hand 11a, forward and backward movement of the returning hand 11b, rotation of the taking hand 11a, rotation of the returning hand 11b, elevation of the taking hand 11a, and elevation of the returning hand 11b.

A storage unit stores a program related to control and a parameter such as a predetermined value. The storage unit may be configured as a single device or may be configured as individual devices corresponding to each control. The indexer block 3 of the present invention has no particular limitation on the configuration of the device that implements the storage unit.

### 8. Flow of Substrate Processing

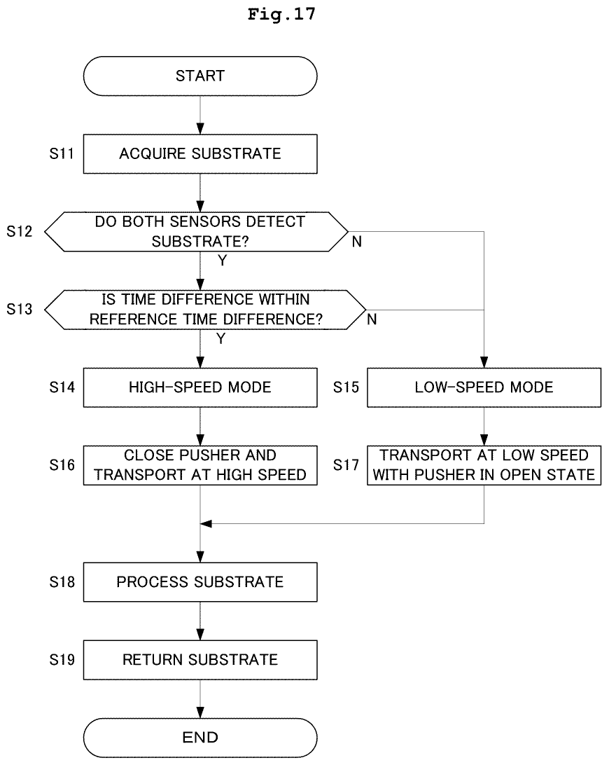

Hereinafter, the flow of substrate processing in the substrate processing apparatus 1 according to the present embodiment will be described with reference to FIG. 17.

Step S11: The substrate W is acquired from the carrier C placed on the load port 10. That is, the taking hand 11a enters the carrier C below the substrate W to be transported, and then ascends to place the substrate W to be transported on the guide member 32a, the guide member 32b, the guide member 34a, and the guide member 34b.

Step S12: The control unit 100 determines whether or not both of the first sensor 22a and the second sensor 22b sense the substrate W. When the determination is true, the process proceeds to step S13, and when the determination is false, the process proceeds to step S15.

Step S13: The control unit 100 determines whether or not the time difference in detection of the substrate W by the first sensor 22a and the second sensor 22b is within the reference time difference. When the determination is true, the substrate W is close to a flat shape, and there is no problem even when the substrate W is transported at a high speed with the pusher 35 in the closed state. In such a case, the process proceeds to step S14. When the determination is false, the substrate W is far from a flat shape, and the substrate W cannot be transported at a high speed with the pusher 35 in the closed state. In such a case, the process proceeds to step S15.

Step S14: The control unit 100 determines that the substrate W placed on the taking hand 11a is flat, and sets the transport mode of the substrate W to the high-speed mode. Thereafter, the process proceeds to step S16.

Step S15: The control unit 100 determines that the substrate W placed on the taking hand 11a is not flat, and sets the transport mode of the substrate W to the low-speed mode. Thereafter, the process proceeds to step S17.

Step S16: The control unit 100 controls the pusher driving mechanism 43 to transport the substrate W at a high speed with the pusher 35 in the closed state. The taking hand 11a retracts from the carrier C and transports the substrate W to the path 24 at a high speed. The transported substrate W is transported to the single-substrate-type processing chamber 5a by the center robot CR.

Step S17: The control unit 100 controls the pusher driving mechanism 43 to transport the substrate W at a low speed while keeping the pusher 35 in the open state. The taking hand 11a retracts from the carrier C and transports the substrate W to the path 24 at a low speed. The transported substrate W is transported to the single-substrate-type processing chamber 5a by the center robot CR.

Step S18: The cleaning processing and the drying processing of the substrate W are executed in the single-substrate-type processing chamber 5a.

Step S19: The processed substrate W is transported to the path 24 by the center robot CR. The returning hand 11b returns the substrate W placed on the path 24 to the carrier C. In this manner, the substrate processing apparatus of the present embodiment performs processing of the substrate.

Steps S11 to S19 describe the operation focusing on one substrate W stored in the carrier C. Therefore, these steps S11 to S19 are repeated by the number of substrates W stored in the carrier C.

### 9. Effects of Present Invention

As described above, the indexer block 3 according to the present invention has the taking hand 11a including the guide member 32a and the guide member 32b. The guide member 32a has the first sensor 22a capable of sensing the substrate W, and the guide member 32b has the second sensor 22b capable of sensing the substrate W. When it is determined whether or not the gripping of the substrate W can be executed using the outputs of the first sensor 22a and the second sensor 22b, the substrate W can be appropriately transported according to the state of the substrate W to be transported. Therefore, according to the indexer block 3 of the present invention, it is possible to efficiently transporting various types of substrates W.

According to the above configuration, the first sensor 22a sensing that the substrate W is placed on the first guide 32a, the second sensor 22b sensing that the substrate W is placed on the second guide 32b, and the pusher 35 provided to face the first guide 32a and the second guide 32b and being movable forward and backward toward the first guide 32a and the second guide 32b are provided. In a case where both of the first sensor 22a and the second sensor 22b respectively sense that the substrate W is placed on the first guide 32a and the second guide 32b, the pusher 35 is allowed to change from the open state to the closed state. On the other hand, in a case where at least one of the first sensor 22a and the second sensor 22b does not sense the substrate W, the pusher 35 is prohibited from changing from the open state to the closed state. With such a configuration, the state of the substrate W can be grasped using the first sensor 22a and the second sensor 22b. That is, in a case where both of the first sensor 22a and the second sensor 22b respectively sense that the substrate W is placed on the first guide 32a and the second guide 32b, it can be determined that the shape of the substrate W is close to a flat shape. On the other hand, in a case where at least one of the first sensor 22a and the second sensor 22b does not sense the substrate W, it can be determined that the shape of the substrate W is far from a flat shape. As described above, when the state of the substrate W is known, the opening and closing of the pusher 35 can be appropriately controlled according to the state of the substrate W. Therefore, according to the present invention, it is possible to provide a substrate transport apparatus capable of efficiently transporting various types of substrates W.

According to the above configuration, even in a case where both of the first sensor 22a and the second sensor 22b respectively sense that the substrate W is placed on the first guide 32a and the second guide 32b, the state of the substrate W can be accurately sensed. That is, according to the above configuration, the time point at which the first sensor 22a senses that the substrate W is placed on the first guide 32a and the time point at which the second sensor 22b senses that the substrate W is placed on the second guide 32b are compared to determine the time difference therebetween. When the determined time difference is within the reference time difference, it can be determined that the shape of the substrate W is close to a flat shape. When the determined time difference exceeds the reference time difference, it can be determined that the shape of the substrate W is far from a flat shape. As described above, when the state of the substrate W is known, the opening and closing of the pusher 35 can be appropriately controlled according to the state of the substrate W. Therefore, according to the present invention, it is possible to provide a substrate transport apparatus capable of efficiently transporting various types of substrates W.

According to the above configuration, it is possible to switch a mode between a mode of moving the hand at a first moving speed and a mode of moving the hand at a second moving speed slower than the first moving speed. When the determined time difference is within the reference time difference, the pusher 35 is changed from the open state to the closed state to move the hand at the first moving speed while the substrate W is caught and held. When the determined time difference exceeds the reference time difference, the hand is moved at the second moving speed while the pusher 35 is prohibited from changing from the open state to the closed state. Also in a case where the pusher 35 is prohibited from changing from the open state to the closed state, the hand is moved at the second moving speed. With such a configuration, a substrate transport apparatus with a high throughput can be realized.

According to the above configuration, when the pusher 35 is prohibited from the open state to the closed state, transport of the substrate W is stopped. With such a configuration, it is possible to provide a substrate transport apparatus in which the substrate W far from a flat shape is not transported and dropping of the substrate W is suppressed. In such a case, since the taking hand 11a returns the substrate W to the original slot, a transport miss can be prevented, and since the process proceeds to the next substrate transport, a decrease in throughput due to the transport stop can also be prevented.

According to the above configuration, the first guide 32a includes the tapered portion B supporting the peripheral edge lower portion of the substrate W and the wall portion A coming into contact with the outer peripheral surface of the substrate W, and the second guide 32b includes the tapered portion B supporting the peripheral edge lower portion of the substrate W and the wall portion A coming into contact with the outer peripheral surface of the substrate W. With such a configuration, it is possible to provide a substrate transport apparatus capable of reliably transporting the substrate W without dropping the substrate W as much as possible.

According to the above configuration, the base member 31 includes the first blade 33a, the second blade 33b, and the connecting portion 36 connecting the first blade 33a and the second blade 33b. The pusher 35 is disposed on the connecting portion 36, the first guide 32a is disposed on the first blade 33a, and the second guide 32b is disposed on the second blade 33b. With such a configuration, it is possible to provide a substrate transport apparatus capable of reliably catching and holding the substrate W.

According to the above configuration, the first sensor 22a and the second sensor 22b are tactile sensors. With such a configuration, it is possible to reliably detect whether or not the substrate W is placed on the first guide 32a and the second guide 32b. According to the above configuration, the first sensor 22a is provided between the base member 31 and the first guide 32a. With such a configuration, the first sensor 22a can reliably detect the placement of the substrate W in the first guide 32a. According to the above configuration, the second sensor 22b is provided between the base member 31 and the second guide 32b. With such a configuration, the same effect as that of the first sensor 22a is obtained.

According to the above configuration, it is preferable to determine that the substrate W is placed on the first guide 32a when the first sensor 22a detects a predetermined load, and to determine that the substrate W is placed on the second guide 32b when the second sensor 22b detects a predetermined load. With such a configuration, it is possible to provide a substrate transport apparatus that does not cause malfunction even when the first sensor 22a and the second sensor 22b detect noise.

According to the above configuration, the first sensor 22a is embedded in the first recess 37a formed in the base member 31, and the second sensor 22b is embedded in the second recess 37b formed in the base member 31. With such a configuration, it is possible to provide a substrate transport apparatus in which the thickness of a hand in a height direction is suppressed and the hand does not collide with the substrate W during transport.

According to the above configuration, a single-substrate-type processing unit processing the substrates W transported by the hand one by one is provided. According to the above configuration, it is possible to provide a substrate processing apparatus capable of performing substrate processing while reliably transporting various types of substrates W.

### 10. Modifications

The present invention is not limited to the above-described embodiments, and modifications as described below can be made.

### Modification 1

The determinations in step S13 and step S14 in FIG. 17 are reflected in the operation of the taking hand 11a, but the present invention is not limited to this configuration. The determination in step S13 can also be used for the displacement operation of the pusher 35 in the returning hand 11b. That is, the substrate W that can be caught and held in step S13 and step S14 can be caught and held by the returning hand 11b in step S19. That is, the substrate W that cannot be caught and held in step S13 and step S14 cannot be caught and held by the returning hand 11b in step S17. As described above, when the determination on the distortion of the substrate W executed by the taking hand 11a is used for the returning operation of the substrate W by the returning hand 11b, the indexer block 3 capable of more reliably transporting the substrate can be provided.

### Modification 2

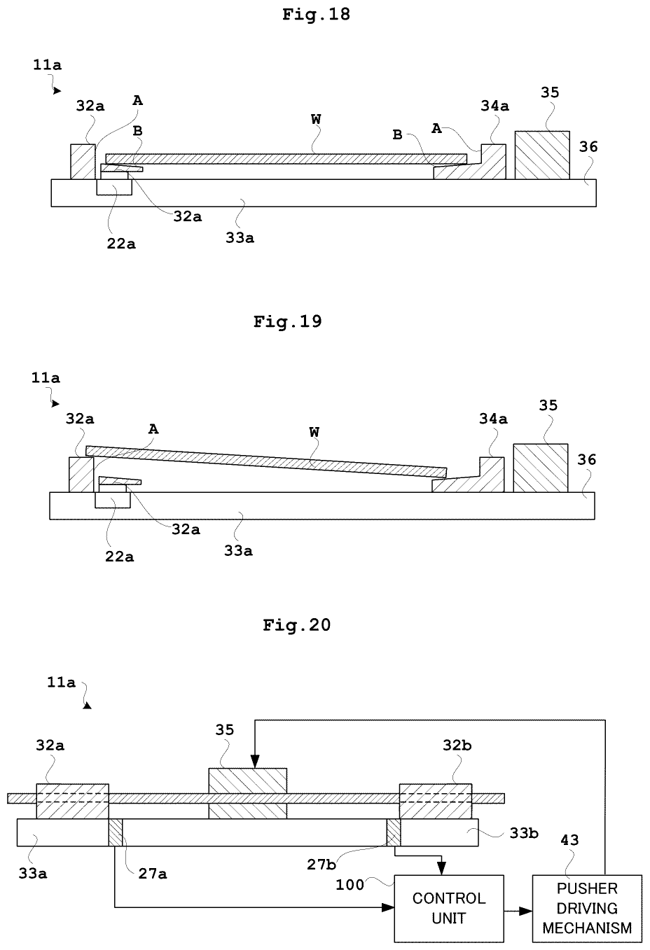

As illustrated in FIG. 18, the guide member 32a may have a configuration in which the support portion (tapered portion B) and the wall portion A are provided to be separated from each other. In this case, the first sensor 22a is provided between the base member 31 and the support portion of the guide member 32a. In the case of the present modification, the guide member 32b may also have a configuration in which the support portion (tapered portion B) and the wall portion A are provided to be separated from each other. In this case, the second sensor 22b is provided between the base member 31 and the support portion of the guide member 32b.

According to the above configuration, in the first guide 32a, the tapered portion B and the wall portion A are separated from each other, and the first sensor 22a is provided between the base member 31 and the tapered portion B of the first guide 32a. With such a configuration, it is possible to provide a substrate transport apparatus capable of detecting that the substrate W has risen on the wall portion A as illustrated in FIG. 19 to determine the state of the substrate W. According to the above configuration, in the second guide 32b, the tapered portion B and the wall portion A are separated from each other, and the second sensor 22b is provided between the base member 31 and the tapered portion B of the second guide 32b. With such a configuration, the second sensor 22b also has the same effect as the first guide 32a described above.

### Modification 3

In the above-described embodiment, the tactile sensor detects that the substrate W is placed on the guide member 32a and the guide member 32b, but the present invention is not limited to this configuration. As illustrated in FIG. 20, a distance measuring sensor 27a may be provided on the first blade 33a, and a distance measuring sensor 27b may be provided on the second blade 33b. The distance measuring sensor 27a is provided at a position displaced from the guide member 32a toward the second blade 33b. The distance measuring sensor 27b is provided at a position displaced from the guide member 32b toward the first blade 33a. With such a configuration, the distance measuring sensor 27a and the distance measuring sensor 27b are covered with the substrate W held by the taking hand 11a, and the presence or absence of the substrate W can be reliably detected.

The distance measuring sensor 27a can sense whether or not the substrate W is placed on the guide member 32a and can also calculate the distance from the distance measuring sensor 27a to the substrate W, so that it can also detect whether or not the substrate W is in a floating state with respect to the guide member 32a. Similarly, the distance measuring sensor 27b can detect whether the substrate is placed on the guide member 32b and the floating of the substrate W with respect to the guide member 32b. Since the distance measuring sensor 27a and the distance measuring sensor 27b can also detect the timing at which the substrate W is placed on the guide member 32a and the guide member 32b, the present modification can also control the pusher 35 by comparing the timings.

### Modification 4

The present invention is not limited to the indexer block 3, and can be generally applied to a substrate transport apparatus including a robot that transports the substrate W in a horizontal posture.

What is claimed is:

1. A substrate transport apparatus having a hand capable of transporting a substrate in a horizontal posture,
wherein the hand includes
a base member,
a first guide provided on an upper surface of the base member, supporting a peripheral edge lower portion of a substrate, and coming in contact with an outer peripheral surface of the substrate,
a first sensor configured to sense that the substrate is placed on the first guide,
a second guide provided on the upper surface of the base member, supporting the peripheral edge lower portion of the substrate, and coming in contact with the outer peripheral surface of the substrate,
a second sensor configured to sense that the substrate is placed on the second guide, and
a pusher provided on the upper surface of the base member to face the first guide and the second guide and being movable forward and backward toward the first guide and the second guide,
the substrate transport apparatus comprises:
a pusher driving unit configured to advance and retract the pusher; and
a control unit configured to control the pusher driving unit,
the control unit is configured to cause the pusher to be switchable between
an open state in which the pusher is separated from the outer peripheral surface of the substrate placed on the first guide and the second guide, and
a closed state in which the pusher comes into contact with the outer peripheral surface of the substrate to press the substrate against the first guide and the second guide and to catch and hold the substrate, and
when the substrate is received by the hand with the pusher in the open state, the control unit is configured
to allow the pusher to change from the open state to the closed state in a case where both of the first sensor and the second sensor respectively sense that the substrate is placed on the first guide and the second guide, and
to prohibit the pusher from changing from the open state to the closed state in a case where at least one of the first sensor and the second sensor does not sense the substrate.

2. The substrate transport apparatus according to claim 1, wherein
in a case where both of the first sensor and the second sensor respectively sense that the substrate is placed on the first guide and the second guide, the control unit is configured
to determine a time difference between a time point at which the first sensor senses that the substrate is placed on the first guide and a time point at which the second sensor senses that the substrate is placed on the second guide by comparing both the time points,
to allow the pusher to change from the open state to the closed state in a case where the time difference is within a predetermined reference time difference, and
to prohibit the pusher from changing from the open state to the closed state in a case where the time difference exceeds the predetermined reference time difference.

3. The substrate transport apparatus according to claim 2, further comprising a transport mechanism configured to move the hand,
wherein the transport mechanism is configured to cause the hand to be switchable between a mode of moving the hand at a first moving speed and a mode of moving the hand at a second moving speed slower than the first moving speed, and
in a case where both of the first sensor and the second sensor respectively sense that the substrate is placed on the first guide and the second guide, the control unit is configured
to determine a time difference between a time point at which the first sensor senses that the substrate is placed on the first guide and a time point at which the second sensor senses that the substrate is placed on the second guide by comparing both the time points,
to allow the pusher to changing from the open state to the closed state to catch and hold the substrate in a case where the time difference is within a predetermined reference time difference, and
to further control the transport mechanism to move the hand catching and holding the substrate at the first moving speed, but
in a case where at least one of the first sensor and the second sensor does not sense the substrate and a case where the time difference exceeds the predetermined reference time difference, the control unit is configured
to prohibit the pusher from changing from the open state to the closed state to bring the substrate in a state of not being caught and held, and
to further control the transport mechanism to move the hand at the second moving speed in a state where the substrate is not caught and held by the pusher.

4. The substrate transport apparatus according to claim 3, wherein the control unit is configured to return the substrate to an original slot instead of moving the hand at the second moving speed in a state where the substrate is not caught and held by the pusher, in a case where at least one of the first sensor and the second sensor does not sense the substrate and a case where the time difference exceeds the predetermined reference time difference.

5. The substrate transport apparatus according to claim 1, wherein
the first guide includes a support portion supporting the peripheral edge lower portion of the substrate and a wall portion coming into contact with the outer peripheral surface of the substrate, and
the second guide includes a support supporting the peripheral edge lower portion of the substrate and a wall portion coming into contact with the outer peripheral surface of the substrate.

6. The substrate transport apparatus according to claim 1, wherein
the base member includes
a first blade,
a second blade, and
a connecting portion connecting the first blade and the second blade,
the pusher is disposed on the connecting portion,
the first guide is disposed on the first blade, and
the second guide is disposed on the second blade.

7. The substrate transport apparatus according to claim 1, wherein
the first sensor is a tactile sensor and is provided between the base member and the first guide, and
the second sensor is a tactile sensor and is provided between the base member and the second guide.

8. The substrate transport apparatus according to claim 7, wherein
in the first guide, the support portion and the wall portion are separated from each other,
the first sensor is provided between the base member and the support portion of the first guide,
in the second guide, the support portion and the wall portion are separated from each other, and
the second sensor is provided between the base member and the support portion of the second guide.

9. The substrate transport apparatus according to claim 7, wherein
the control unit is configured
to determine that the substrate is placed on the first guide when the first sensor detects a predetermined load, and
to determine that the substrate is placed on the second guide when the second sensor detects a predetermined load.

10. The substrate transport apparatus according to claim 7, wherein
the first sensor is embedded in a first recess formed in the base member, and
the second sensor is embedded in a second recess formed in the base member.

11. A substrate processing apparatus including the substrate transport apparatus according to claim 1, the substrate processing apparatus comprising a single-substrate-type processing unit configured to process substrates transported by the hand one by one.
